(19) United States
(12) Patent Application Publication
(10) Pub. No.: US 2021/0047735 A1
(43) Pub. Date: Feb. 18, 2021

(54) COMPOSITION FOR ELECTROLESS COPPER PLATING AND METHOD FOR ELECTROLESS PLATING USING THE SAME

(71) Applicant: SAMSUNG ELECTRO-MECHANICS CO., LTD., Suwon-si (KR)

(72) Inventors: Young Sub SIN, Suwon-si (KR); Su Jin LEE, Suwon-si (KR); Cheol Min BAE, Suwon-si (KR); Cheol Min KIM, Suwon-si (KR)

(21) Appl. No.: 16/742,647

(22) Filed: Jan. 14, 2020

(30) Foreign Application Priority Data
Aug. 13, 2019 (KR) 10-2019-0098761

(51) Int. Cl. C23C 18/38

(52) U.S. Cl. CPC C23C 18/38

(57) ABSTRACT

The present disclosure relates to an electroless copper plating composition and an electroless plating method and a product using the same.

### CROSS-REFERENCE TO RELATED APPLICATION(S)

This application claims the priority of Korean Patent Application No. 10-2019-0098761 filed on Aug. 13, 2019, in the Korean Intellectual Property Office, the disclosure of which is incorporated herein by reference.

### BACKGROUND

### 1. Field

The present disclosure relates to an electroless copper plating composition and a method for electroless plating using the same.

### 2. Description of Related Art

For the thinning and high integration of electronic devices, patterns of printed circuit boards are becoming gradually thinner and thinner and refined, and copper (Cu) having excellent resistivity is mainly used as a wiring material.

In order to form an appropriate copper pattern on a common printed circuit board, a conductive seed layer for electroplating is formed using electroless chemical copper plating, and then a photoresist is exposed to light through a photo-resistor PR to form a pattern. Thereafter, if copper electroplating is selectively performed only on portions exposed to the seed layer, a copper pattern is formed to a thickness of about 15 μm.

However, in recent years, as high-end products of multilayer thin films are developed to meet customer needs, defects are increasing due to pattern refinement. That is, pattern lifting may occur due to a decrease in adhesion between a pattern and an epoxy under the pattern due to the pattern refinement, a defect increases due to an unnecessary copper foreign material between the formed patterns.

Therefore, there is a continuous need to secure throwing power (T/P) by reducing the thickness of the chemical copper plating and reducing the surface thickness to solve the above problems.

As background art of the present disclosure, Korean Patent Registration No. 10-1585200 (2016.01.07) describes a copper plating solution composition and a method for copper plating using the same.

### SUMMARY

The present disclosure relates to an electroless copper plating composition capable of improving throwing power (T/P) even in pattern refinement by changing a composition of a component affecting throwing power of the copper plating composition component, in order to prevent a risk of a via open due to occurrence in a filling problem in a via hole when the thickness of the chemical copper plating surface is reduced.

In addition, the present disclosure relates to an electroless copper plating composition without a pattern lifting phenomenon due to pattern refinement and defects due to copper foreign materials even when the chemical copper plating thickness is lowered.

Furthermore, the present disclosure relates to a method for preparing an electroless copper plating capable of implementing high throwing power of copper plating even when the surface thickness of chemical copper plating is reduced while maintaining normal standard plating process conditions using the electroless copper plating composition and provide a product thereof.

According to one aspect, an electroless copper plating composition includes a copper solution (A) including a copper salt, a nickel salt, and a complexing agent; a basic solution (B) including a nickel salt, a complexing agent, and a basic compound; and a stabilizer (C). The total content of the nickel salt is 0.05 to 1 part by weight, inclusive, relative to the total weight of the copper solution (A) and the basic solution (B).

According to one embodiment, the content of the nickel salt in the basic solution (B) may be 0.05 to 1 part by weight, inclusive, relative to the total weight of the basic solution (B).

According to one embodiment, the content of the nickel salt in the copper solution (A) may be 0.05 or more and less than 0.5 parts by weight, relative to the total weight of the copper solution (A).

According to one embodiment, the content of the copper salt in the copper solution (A) may be 10 to 15 parts by weight, inclusive, relative to the total weight of the copper solution (A).

According to one embodiment, the copper salt may be copper sulfate (CuSO₄), and the nickel salt may be nickel sulfate (NiSO₄).

According to one embodiment, the complexing agent in the copper solution (A) comprises tartaric acid, and the content of the tartaric acid may be 1 to 5 parts by weight, relative to the total weight of the copper solution (A).

According to one embodiment, the complexing agent in the basic solution (B) comprises a Rochelle salt, and the content of the Rochelle salt may be 35 to 45 parts by weight, relative to the total weight of the basic solution (B).

According to one embodiment, the content of the basic compound may be 5 to 10 parts by weight, relative to the total weight of the basic solution (B).

According to one embodiment, the content of the stabilizer may be 1 to 10 parts by weight, relative to the total weight of the electroless copper plating composition.

According to one embodiment, the stabilizer may comprise NaCN.

According to one embodiment, the electroless copper plating composition further comprises 1 to 5 parts by weight of a starter, relative to the total weight of the electroless copper plating composition.

According to one embodiment, the electroless copper plating composition further comprises 10 to 20 parts by weight of a reducing agent, relative to the total weight of the electroless plating solution.

In another aspect, a product copper plated with the electroless copper plating composition is provided.

According to one embodiment, a thickness of the electroless copper plating of the product may be 0.8 μm or less.

According to one embodiment, the product may have throwing power (T/P) of 65% or more.

According to one embodiment, the product may have a line/space (L/S) of 5 μm/5 μm or less.

According to one embodiment, the product may be a printed circuit board, an integrated circuit board, a panel level package (PLP), a redistribution layer (RDL), an interconnect device, a wafer, a display component or a plastic component.

According to another aspect, a method for preparing an electroless copper plating, including a step of dipping a product in an electroless copper plating composition, is provided.

According to one embodiment, in the method for preparing an electroless copper plating, a dipping time of the dipping step may be 5 to 15 minutes.

According to one embodiment, in the method for preparing an electroless copper plating, the throwing power (T/P) may be 65% or more.

According to one embodiment, when the surface thickness of the chemical copper plating is reduced, despite the pattern refinement, throwing power (T/P) may be remarkably improved, thereby preventing a risk of a via opening due to a filling problem in via holes.

According to one embodiment, even when the thickness of the chemical copper plating is reduced, a pattern lifting phenomenon due to pattern refinement and a defect due to a copper foreign material may be significantly minimized.

According to one embodiment, the copper plating may be performed with high throwing power even when the surface thickness of chemical copper plating is reduced while maintaining normal plating process conditions using the electroless copper plating composition of the present disclosure.

According to one embodiment, while significantly reducing the thickness of plating, by improving throwing power to about 65% or more, it is possible to provide a product for realizing a next generation fine line/space.

Other objects and advantages of the present disclosure will be apparent from the following detailed description, claims and drawings.

### BRIEF DESCRIPTION OF DRAWINGS

The above and other aspects, features and other advantages of the present invention will be more clearly understood from the following detailed description taken in conjunction with the accompanying drawings, in which:

FIG. 1A illustrates a variability chart of a chemical copper plating thickness after chemical copper plating using a copper plating composition of Comparative Examples 1 and 2 according to the present disclosure;

FIG. 1B illustrates a variability chart of throwing power after chemical copper plating using a copper plating composition of Comparative Examples 1 and 2 according to the present disclosure;

FIG. 2A illustrates a variability chart of chemical copper plating thickness after chemical copper plating using a copper plating composition of Comparative Examples 1, 3, and 4 according to the present disclosure;

FIG. 2B illustrates a variability chart of a throwing power after chemical copper plating using a copper plating composition of Comparative Examples 1, 3, and 4 according to the present disclosure;

FIG. 3A illustrates a variability chart of a chemical copper plating thickness after chemical copper plating using the copper plating composition of Comparative Examples 1, 5, and 6 and Examples 1 to 3 according to the present disclosure;

FIG. 3B illustrates a variability chart of a throwing power after chemical copper plating using the copper plating composition of Comparative Examples 1, 5, and 6 and Examples 1 to 3 according to the present disclosure;

FIG. 4 illustrates results of a throwing power test after chemical copper plating using composition ratios of the copper plating compositions of Comparative Examples 1, 5, and 6, and Examples 1 to 3 according to the present disclosure and respective compositions;

FIG. 5A illustrates a variability chart of a chemical copper plating thickness after chemical copper plating using the copper plating compositions of Comparative Example 7, and Examples 4 to 6 according to the present disclosure;

FIG. 5B illustrates a result of an one way analysis of the chemical copper plating thickness after chemical copper plating using the copper plating composition of Comparative Example 7 and Example 1 according to the present disclosure;

FIG. 6A illustrates a result of throwing power after chemical copper plating using the copper plating composition of Comparative Example 1 according to the present disclosure;

FIG. 6B illustrates a result of throwing power after chemical copper plating using the copper plating composition of Example 1 according to the present disclosure;

FIG. 7A illustrates a variability chart of a chemical copper plating thickness after chemical copper plating using the copper plating compositions of Comparative Example 1 and Example 1 according to the present disclosure;

FIG. 7B illustrates a variability chart of throwing power after chemical copper plating using the copper plating compositions of Comparative Example 1 and Example 1 according to the present disclosure;

FIG. 8 illustrates a peel strength measurement result after chemical copper plating using the copper plating compositions of Comparative Example 1 and Example 1 according to the present disclosure; and

FIG. 9 illustrates results of confirming a coverage in a via in a product using the electroless copper plating composition according to an embodiment of the present disclosure.

### DETAILED DESCRIPTION

Embodiments of the present disclosure will now be described in detail with reference to the accompanying drawings. The disclosure may, however, be embodied in many different forms and should not be construed as being limited to the embodiments set forth herein. Rather, it should be understood to include all transformations, equivalents, and substitutes included in the spirit and scope of the present disclosure.

The terminology used herein describes particular embodiments only, and the present disclosure is not limited thereby. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

In the following description of the present disclosure, if it is determined that the detailed description of the related known technology may obscure the gist of the present disclosure, the detailed description thereof will be omitted.

Hereinafter, embodiments of the present disclosure will be described in detail with reference to the accompanying drawings. In the following description of the present disclosure, the same reference numerals will be used for the same means regardless of the reference numerals in order to facilitate the overall understanding.

1. Electroless Copper Plating Composition

According to an aspect, an electroless copper plating composition includes a copper solution (A) including a copper salt, a nickel salt, and a complexing agent; and a basic solution (B) including a nickel salt, a complexing agent, and a basic compound; and a stabilizer (C), a total content of the nickel salt in the copper plating composition may be 0.05 to 1 part by weight, inclusive, relative to a total weight of the copper solution (A) and the basic solution (B).

The total content of the nickel salt in the copper plating composition may be 0.05 to 1 part by weight, inclusive, relative to the total weight of the copper solution (A) and the basic solution (B), 0.05 to 0.5 parts by weight may be suitable, and 0.1 to 0.4 parts by weight may be more suitable.

1) Copper Solution (A)

A copper solution (A) in the electroless copper plating composition may include a copper salt, a nickel salt, and a complexing agent.

The copper salt is for providing copper (Cu) ions, but is not limited thereto, and may include one selected from the group consisting of copper sulfate(CuSO₄), copper chloride(CuCl₂), copper hydroxide (Cu(OH)₂), and the like, and copper sulfate (CuSO₄) may be suitable.

The content of the copper salt is not limited thereto, but may be 10 to 15 parts by weight, inclusive, relative to the total weight of the copper solution (A).

When the content of the copper salt is less than 10 parts by weight, relative to the total weight of the copper solution (A), a supply of Cu ions may be slowed down, and a plating rate may be reduced. When the content of the copper salt exceeds 15 parts by weight, a film formation and stability of the plating solution may be significantly reduced. In one embodiment, the content of copper sulfate (CuSO₄) in the copper solution (A) may be 10 to 15 parts by weight, inclusive, relative to the total weight of the copper solution (A).

The nickel salt may promote oxidation of a reducing agent and increase the plating rate. In addition, by reducing generation of hydrogen, the nickel salt is an important factor to increase throwing power during copper plating. The type of nickel salt is not limited thereto, but may include one selected from the group consisting of nickel sulfate (NiSO₄), nickel chloride (NiCl₂), nickel acetate (Ni(CH₃COO)₂), methane sulfonate (Ni(CH₃SO₃)₂) and nickel carbonate (NiCO₃), and nickel sulfate (NiSO₄) may be suitable.

The content of the nickel salt in the copper solution (A) is not limited thereto, but it may be 0.05 or more and less than 0.5 parts by weight, relative to the total weight of the copper solution (A). When the content of the nickel salt is less than 0.05 parts by weight, relative to the total weight of the copper solution (A), oxidation of the reducing agent may not be promoted, and the plating rate may be slow. When it is 0.05 parts by weight or more, it may be difficult to obtain throwing power according to the present disclosure. In one embodiment, the content of nickel sulfate (NiSO₄) in the copper solution (A) may be 0.05 or more and less than 0.5 parts by weight, relative to the total weight of the copper solution (A).

The complexing agent of copper ions comprises tartrate, which is polycarboxylic acid containing a hydroxyl group, especially potassium sodium tartrate and citrate, known as Rochelle salt, and ethylenediaminetetraacetic acid (EDTA), which is amino acid containing a carboxyl group, pentetinic acid (DTPA), which is trilon, a nitrilotriacetic acid (NTA), cyclohexane 1,2-diaminetetraacetic acid (CDTA), diamines containing hydroxyl groups, N,N,N,N′-tetrakis (2-hydroxypropyl) ethylenediamine (THPED), known under a product name Quadrol and N,N,N,N′-tetrakis (2-hydroxyethyl) ethylenediamine (THPED), triethanolamine (TEA), which is a monoamine containing a hydroxyl group, and triisopropanolamine (TIPA), and the like.

The complexing agent is not limited thereto, but tartaric acid may be suitable.

The content of the complexing agent is not limited thereto, but may be 1 to 5 parts by weight, relative to the total weight of the copper solution (A). When the content of the complexing agent is less than 1 part by weight, relative to the total weight of the copper solution (A), it may not have a stabilizing effect due to a chelation effect with copper ions, and when the content of the complexing agent exceeds 5 parts by weight, a precipitation rate may be reduced.

2) Basic Solution (B)

A basic solution (B) in the electroless copper plating composition may include a nickel salt, a complexing agent, and a basic compound.

The nickel salt in the basic solution (B) serves to promote oxidation of a reducing agent and to increase a plating rate, as in the copper solution (A). In addition, by reducing generation of hydrogen, the nickel salt is an important factor to increase throwing power during copper plating. The type of nickel salt is not limited thereto, but may include one selected from the group consisting of nickel sulfate (NiSO₄), nickel chloride (NiCl₂), nickel acetate (Ni(CH₃COO)₂), methane sulfonate (Ni(CH₃SO₃)₂, and nickel carbonate (NiCO₃), and nickel sulfate (NiSO₄) may be most suitable.

The total content of the nickel salt may be 0.05 to 1 part by weight, inclusive, relative to the total weight of the copper solution (A) and the basic solution (B), and 0.05 to 0.5 may be more suitable, inclusive, and 0.1 to 0.4, inclusive, may be most suitable.

The content of the nickel salt in the basic solution (B) is not limited thereto, but may be 0.05 to 1 part by weight, inclusive, relative to the total weight of the basic solution (B). When the content of the nickel salt is less than 0.05 part by weight, relative to the total weight of the basic solution (B), it cannot promote oxidation of the reducing agent, and a plating rate may be slowed down. When the content of the nickel salt is 1 part by weight or more, it may be difficult to obtain throwing power according to the present disclosure. In one embodiment, the content of nickel sulfate (NiSO₄) in the basic solution (B) may be 0.05 to 1 part by weight, inclusive, relative to the total weight of the basic solution (B).

The complexing agent in the basic solution (B) comprises tartrate, which is polycarboxylic acid containing a hydroxyl group, in particular, sodium potassium tartrate and citrate, known as a Rochelle salt, and ethylenediaminetetraacetic acid (EDTA), which is amino acid containing a carboxyl group, pentetinic acid (DTPA), which is trilon, nitrilotriacetic acid (NTA), cyclohexane 1,2-diaminetetraacetic acid (CDTA), diamines containing hydroxyl groups, N,N,N,N′-tetrakis (2-hydroxypropyl) ethylenediamine (THPED), known under a product name Quadrol and N,N,N,N′-tetrakis (2-hydroxyethyl) ethylenediamine (THPED), triethanolamine (TEA), which is a monoamine containing a hydroxyl group, and triisopropanolamine (TIPA), and the like.

The complexing agent is not limited thereto, but a Rochelle salt (tetrahydrate type) may be suitable.

The content of the complexing agent is not limited thereto, but may be 1 to 5 parts by weight relative to the total weight of the basic solution (B).

When the content of the complexing agent is less than 1 part by weight, relative to the total weight of the basic solution (B), it may not have a stabilizing effect due to a chelate effect with copper ions, and when the content of the complexing agent exceeds 5 part by weight, a precipitation rate may be reduced.

The basic compound included in the basic solution serves as a pH adjuster, but is not limited thereto, and it may be suitable that the pH of the basic solution is 11 to 14, and it may be more suitable that the pH is 12.5 to 14.

The basic compound is not limited thereto and may include potassium hydroxide (KOH), sodium hydroxide (NaOH), lithium hydroxide (LiOH), cesium hydroxide (CsOH), rubidium hydroxide (RbOH), ammonium hydroxide (NH₄OH), tetramethylammonium hydroxide (TMAH) or tetrabutylammonium hydroxide (TBAH) and mixtures thereof, of which sodium hydroxide (NaOH) may be suitable.

Due to the basic compound included in the basic solution (B), the basic solution (B) has a relatively higher pH than the copper solution (pH of the copper solution (A) is 0.1 to 2).

3) Stabilizer (C)

A stabilizer (C) may further extend a lifespan of an electroless copper plating bath and may help prevent unwanted decomposition of the plating bath.

The stabilizer is not limited thereto, but may include dipyridyl (2,2′-dipyridyl, 4,4′-dipyridyl), phenanthroline, mercaptobenzothiazole, derivatives thereof such as thiourea or diethylthiourea, cyanide such as NaCN and KCN, ferrocyanide such as K₄[Fe(CN)₆], thiocyanate, iodide, ethanolamine, mercaptobenzotriazole, Na₂S₂O₃, polyacrylamide, polyacrylate, polymers such as polyethylene glycol or polypropylene glycol, and copolymers thereof, wherein the stabilizer may include one selected from, the group consisting of K₄[Fe(CN)₆], NaCN, and mercaptobenzothiazole.

As a currently commercially available stabilizer, a Printoganth MV PLUS stabilizer containing NaCN from ATOTEC may be most suitable, but a Printoganth TP1 stabilizer from ATOTEC may not be suitable.

The Atotec Printoganth MV PLUS stabilizer is contained in the NaCN 0.025 or more to less than 0.25% by weight.

A content of the stabilizer may be 1 to 10 parts by weight relative to the total weight of the electroless copper plating composition. The content of the stabilizer is not limited thereto, but when the content of the stabilizer is less than 1 part by weight, relative to the total weight of the electroless copper plating composition, an effect of stabilizing the electroless copper plating solution is insignificant, and when the content of the stabilizer exceeds 10 parts by weight, throwing power (T/P) may be lowered to a conventional level.

4) Other Additives

An electroless copper plating composition may further include a starter and a reducing agent.

The starter is not limited thereto, but may include one selected from the group consisting of, for example, isophthaloybiscaprolactam, N-acetalcaprolactam, isocyanate epsilon-caprolactam additives, alcohols (ROH, wherein R is C1-C12 alkyl), Diol (HO—R—OH, wherein R is C1-C12 alkylene), omega-aminocaproic acid, and sodium methoxide.

As a commercially available starter, Atotec Printoganth MV PLUS starter may be most suitable, but Atotec Printoganth TP1 starter may not be suitable.

The Atotec Printoganth MV Plus starter contains 1 to 2.5% by weight of isopropyl alcohol and 0.1 to 1% by weight of 2,2′-bipyridyl, and the Atotec Printoganth TP1 starter contains less than 1% by weight of 2,2′-bipyridyl.

The content of the starter is not limited thereto, buy may be 1 to 5 parts by weight, relative to the total weight of the electroless copper plating composition. The content of the starter is not limited thereto, but when the content of the starter is less than 1 part by weight, relative to the total weight of the electroless copper plating composition, plating may be peeled off and properties such as chemical resistance on the surface may be reduced. In addition, when the content of the starter exceeds 5 parts by weight, there is a disadvantage of lowering hardenability.

A reducing agent is not limited thereto, but may be selected from, for example, formaldehyde, paraformaldehyde, glyoxylic acid, or a source of glyoxylic acid, aminoboranes such as dimethylamino borane, alkali borides, alkali borides such as NaBH₄, KBH₄, NaH₂PO₂, hydrazine, polysaccharides or sugars, for example, glucose, phosphoric acid, glycolic acid, or formic acid, and the like.

The content of the reducing agent is not limited thereto, but may be 10 to 20 parts by weight, relative to the total weight of the electroless plating solution composition.

By using the electroless copper plating composition of the present disclosure, by improving the throwing power, even in the case of pattern refinement, defects caused by pattern lifting and vibrations can be prevented, and reliability of a via hole, that is, the a plating filling ability in the via hole can be improved.

2. Product

The electroless copper plating composition of the present disclosure can be used for various known substrates capable of copper plating, but is not limited thereto, but may be used in a printed circuit board, an integrated circuit board, a panel level package (PLP), and a redistribution layer (RDL), an interconnect device, a wafer, a display part or a plastic part, and the like.

The product may have a plating having a thickness of 0.8 μm or less.

The product may have throwing power (T/P) of 65% or more.

The product may have a line/space (L/S) of 12 μm/9 μm or less, can be suitable for 5 μm/5 μm or less, to provide a product that realizes a next generation fine line/space.

When the electroless copper plating composition of the present disclosure is used, even when the surface thickness of the chemical copper plating is lowered, a problem of the reliability of the via hole penetrating through upper and lower portions of the product, that is, the filling ability of plating in the via hole do not occur, and there is an advantage of capable or reducing a risk of a via open when mounting a chip on a substrate.

3. Method for Electroless Copper Plating

A method for electroless copper plating may use various known methods to plate a substrate surface using the method for electroless copper plating of the present disclosure.

The method for electroless plating of the present disclosure proceeds in an order of decreasing, activating, reducing, and electroless copper plating, and after each treatment step, an effect of an entire process may be significantly reduced by a washing treatment.

A condition of the method for copper plating is not limited thereto, but may be the same as in Table 1 below.

The method for electroless copper plating of the present disclosure may include a step of dipping a product in the electroless copper plating composition of the present disclosure on the substrate surface.

The dipping time is not limited thereto, but may be 5 to 15 minutes.

A method for copper plating using a conventional composition has throwing power (T/P) of 46% at 10′30″, but when the composition of the present disclosure is used, the copper plating method may have throwing power of 65% or more at the same dipping time thereof.

A drying bath temperature is not limited thereto, but may be 20 to 40° C., and 30 to 35° C. may be suitable.

TABLE 1

| Drying bath concentration (ml/L) | | Dipping time | Temperature(° C.) |
|---|---|---|---|
| Copper solution (A, | 65 | 10.30 min | 31 |
| ml/L) | | | |
| Basic solution (B, | 100 | | |
| ml/L) | | | |
| Stabilizer(ml/L) | 2 | | |
| Starter (ml/L) | 3.8 | | |
| NaOH | 6 | | |
| HCHO | 16 | | |

Hereinafter, Examples of the present disclosure will be described in detail. However, the following Examples merely illustrate the present disclosure, but the present disclosure is not limited by the following Examples.

### EXAMPLE

1. Manufacturing an Electroless Copper Plating Composition

Comparative Examples 1 to 7 and Examples 1 to 6 were designed to identify factors affecting throwing power and to manufacture an electroless copper plating composition capable of improving throwing power (See. Table 2).

TABLE 2

| NO. | Contends |
|---|---|
| Comparative | MV PLUS (POR) (Dipping time: 11′30″) |
| Example 1 | |
| Comparative | TP1 PLUS + TP1 PLUS Stabilizer |
| Example 2 | |
| Comparative | MV PLUS (Cu/Basic) + TP1 PLUS Stabilizer + TP1 PLUS |
| Example 3 | Moderator (content of moderator: 3.0 ml/L/L) |
| Comparative | MV PLUS (Cu/Basic) + TP1 PLUS Stabilizer + TP1 PLUS |
| Example 4 | Moderator (content of moderator: 6.0 ml/L/L) |
| Comparative | MV PLUS (POR) + TP1 PLUS Stabilizer |
| Example 5 | |
| Comparative | MV PLUS (POR) + TP1 PLUS Stabilizer + TP1 PLUS |
| Example 6 | Moderator |
| Comparative | MV PLUS (POR)(Dipping time: 10′30″) |
| Example 7 | |
| Example 1 | TP1 PLUS (Cu/Basic) + MV PLUS Stabilizer (content of |
| | stabilizer: 2.0 ml/L/L, dipping time: 11′30″) |
| Example 2 | TP1 PLUS (Cu/Basic) + MV PLUS Stabilizer (content of |
| | stabilizer: 4.0 ml/L/L) |
| Example 3 | TP1 PLUS (Cu/Basic) + MV PLUS Stabilizer(content of |
| | stabilizer: 6.0 ml/L/L) |
| Example 4 | TP1 PLUS (Cu/Basic) + MV PLUS Stabilizer(content of |
| | stabilizer: 2.0 ml/L/L, dipping time: 9′30″) |
| Example 5 | TP1 PLUS (Cu/Basic) + MV PLUS Stabilizer(content of |
| | stabilizer: 2.0 ml/L/L, dipping time: 8′30″) |
| Example 6 | TP1 PLUS (Cu/Basic) + MV PLUS Stabilizer(content of |
| | stabilizer: 2.0 ml/L/L, dipping time: 7′30″) |

### COMPARATIVE EXAMPLES 1 TO 7

In Comparative Example 1, an electroless copper plating composition was manufactured by a composition according to Table 3, using the copper solution (A) and the basic solution(B) of the conventional MV plus drug (Atotech Co., Ltd.).

In Comparative Example 2, an electroless copper plating composition was manufactured by a composition according to Table 3, using the copper solution (A) and the basic solution (B) of a TP1 drug (Atotech Co., Ltd.).

In Comparative Example 3, an electroless copper plating composition was manufactured in the same manner as in Comparative Example 1, except that a starter and an MV plus stabilizer included in the configuration of Comparative Example 1 was changed to a TP1 moderator and a TP1 stabilizer.

In Comparative Example 4, an electroless copper plating composition was manufactured in the same manner as in Comparative Example 1, except for changing the content of the TP1 moderator from 3.0 mι/L to 6.0 mι/L in the configuration of Comparative Example 3.

In Comparative Example 5, an electroless copper plating composition was manufactured in the same manner as in Comparative Example 1, except that the TP1 stabilizer was added to the composition of Comparative Example 1.

In Comparative Example 6, an electroless copper plating composition was manufactured in the same manner as in Comparative Example 5, except that the TP1 moderator is added to the composition of Comparative Example 5.

In Comparative Example 7, an electroless copper plating composition was manufactured in the same manner as in the configuration of Comparative Example 1, except that only the dipping time was changed from 11′30″ to 10′30″ in the configuration of Comparative Example 1.

TABLE 3

| Composition | | | CE 1 | CE 2 | CE 3 | CE 4 | CE 5 | CE 6 | CE7 |
|---|---|---|---|---|---|---|---|---|---|
| TEST | Composition 1 | Copper solution(A, ml/L) | 65 | — | 65 | 65 | 65 | 65 | 65 |
| composition | (MV plus) | Basic solution(B, ml/L) | 100 | — | 100 | 100 | 100 | 100 | 100 |
| | | Starter(ml/L) | 3.8 | — | — | — | 3.8 | 3.8 | 3.8 |
| | | MV plus stabilizer(ml/L) | 2.0 | — | — | — | 2.0 | 2.0 | 2.0 |
| | Composition 2 | Copper solution(A, ml/L) | — | 65 | — | — | — | — | — |
| | (TP1) | Basic solution(B, ml/L) | — | 100 | — | — | — | — | — |
| | | TP1 moderator(ml/L) | — | 0.6 | 3.0 | 6.0 | — | 3.0 | — |
| | | TP1 stabilizer | — | 3.0 | 0.6 | 3.0 | 1.2 | 1.2 | — |

| NaOH(g/L) | 6 | |
|---|---|---|
| HCHO(ml/L) | 16 | |
| Temperature(° C.) | 31 | |
| Dipping time | 11′30″ | 10′30″ |

*CE: Comparative Example

### EXAMPLES 1 TO 6

In Example 1, an electroless copper plating composition was manufactured in a composition according to Table 4, using a copper solution (A) and a basic solution (B) and of a TP1 drug from (Atotech Co., Ltd.) and an MV Plus starter and a MV Plus stabilizer.

In Example 2, an electroless copper plating composition was manufactured in the same manner as in the configuration of Example 1, except that the content of the MV Plus stabilizer is changed from 2.0 mι/L to 4.0 mι/L.

In Example 3, an electroless copper plating composition is manufactured in the same manner as Example 1, except that the content of the MV Plus stabilizer was changed from 2.0 mι/L to 6.0 mι/L.

In Examples 4 to 6, an electroless copper plating composition was manufactured in the same manner as in Example 1 except for changing a dipping time, respectively.

TABLE 4

| Composition | | | E1 | E2 | E3 | E4 | E5 | E6 |
|---|---|---|---|---|---|---|---|---|
| TEST | Composition 1 | Copper solution(A, ml/L) | — | — | — | — | — | — |
| composition | (MV plus) | Basic solution(B, ml/L) | — | — | — | — | — | — |
| | | MV Plus Starter(ml/L) | 3.8 | — | — | 3.8 | 3.8 | 3.8 |
| | | MV plus stabilizer(ml/L) | 2.0 | 4.0 | 6.0 | 2.0 | 2.0 | 2.0 |
| | Composition 2 | Copper solution(A, ml/L) | 65 | 65 | 65 | 65 | 65 | 65 |
| | (TP1) | Basic solution(B, ml/L) | 100 | 100 | 100 | 100 | 100 | 100 |
| | | TP1 moderator(ml/L) | — | — | — | — | — | — |
| | | TP1 stabilizer | — | — | — | — | — | — |

| NaOH(g/L) | 6 | | | |
|---|---|---|---|---|
| HCHO(ml/L) | 16 | | | |
| Temperature(° C.) | 31 | | | |
| Dipping time | 11′30″ | 9′30″ | 8′30″ | 7′30″ |

*E: Example

The composition of the copper solution (A) and the basic solution (B) shown in Table 3 above is the same as in Table 5, and the composition of the copper solution (A) and the basic solution (B) of the composition 2 shown in Tables 3 and 4 is the same as in Table 6 (% in Table 4 means the weight %).

TABLE 5

| | | Copper | Basic |
|---|---|---|---|
| Composition 1 | | solution(A) | solution(B) |
| Composition | CuSO₄ | 15.4% | 1.3% |
| component | NiSO₄ | 0.5% | 36.2% |
| | Complexing agent | 2.4% | 12.2% |
| Cation | Cu | 6.1% | 0.5% |
| | Ni | 0.2% | 9.8% |
| | Na | trace | 5.0% |
| Anion | SO₄²⁻ | 9.5% | 0.6% |
| | Tartrate | 2.4% | 19.1% |
| Basic property | pH | 0.7 | 13.7 |
| Surface tension | mN/m | 73.7 | 83.3 |

TABLE 6

| | | Copper | Basic |
|---|---|---|---|
| Composition 2 | | solution(A) | solution(B) |
| Composition | CuSO₄ | 14.4% | 0.2% |
| component | NiSO₄ | 0.1% | 38.8% |
| | Complexing agent | 2.4% | 9.9% |
| Cation | Cu | 5.7% | 0.07% |
| | Ni | 0.05% | 8.9% |
| | Na | 23 ppm | 5.4% |
| Anion | SO₄²⁻ | 8.7% | 0.1% |
| | Tartrate | 2.4% | 20.5% |
| Basic property | pH | 0.9 | 13.9 |
| Surface tension | mN/m | 74.6 | 81.0 |

### EXPERIMENTAL EXAMPLE

Using the electroless copper plating compositions of Comparative Examples 1 to 6 and Examples 1 to 3 manufactured above, copper plating was carried out, and then a throwing power (T/P) was evaluated.

In order to measure throwing power (T/P) of a copper plated material according to the present disclosure, a product of 30 μmT and 60 μmΦ was used (in a specific general name), and it was verified by each ABF material (T31, GL102, and GCP) to confirm unplating in vias of the product. In addition, in order to confirm adhesion, peel strength of the plated product was confirmed (see. Table 7).

TABLE 7

| Analysis contents | Metrology |
|---|---|
| Chemical copper plating thickness | Sheet resistance measuring |
| | equipment |
| Throwing power | X-section & SEM |
| Adhesion | Peel strength |

1. Throwing Power Primary Evaluation

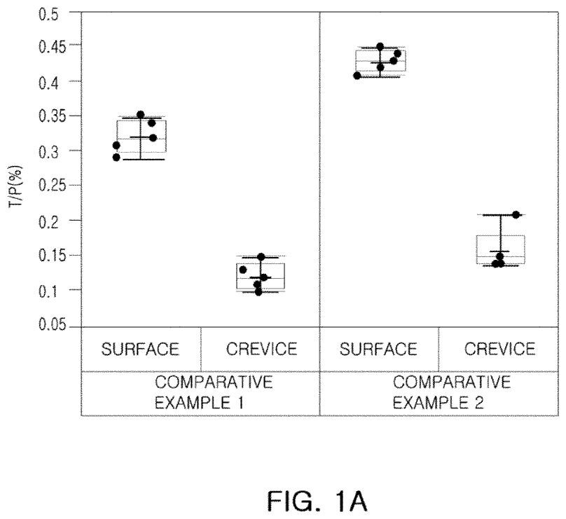

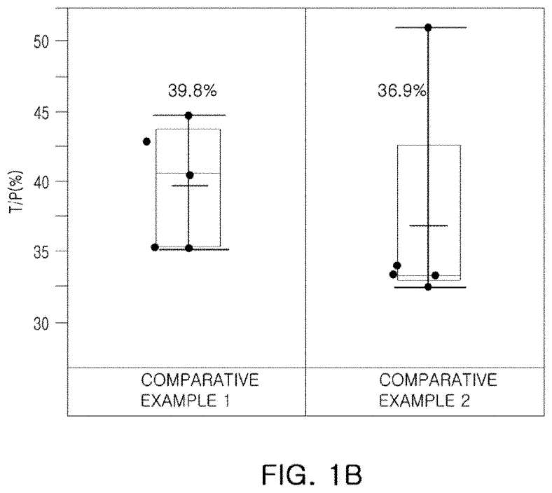

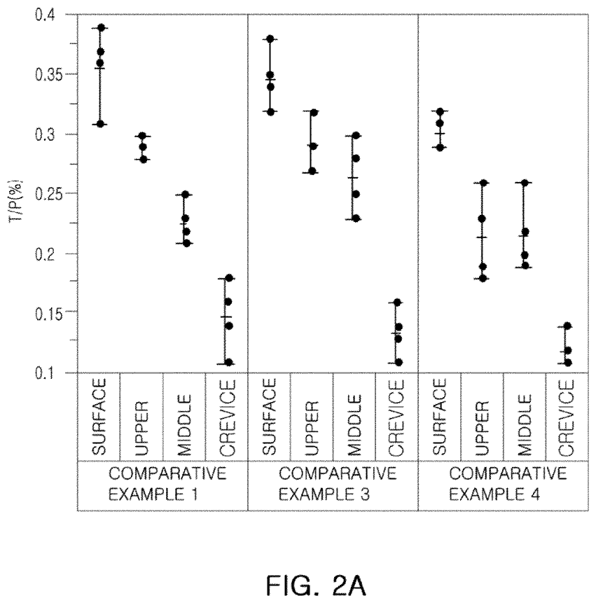

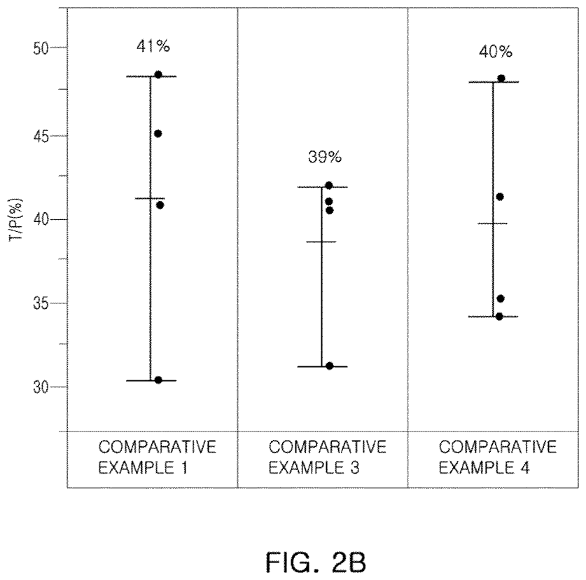

FIGS. 1A and 1B and FIGS. 2A and 2B show results of comparing throwing powers (T/P, %) of Comparative Examples 1 and 2 and results of comparing throwing powers (T/P, %) of Comparative Examples 1, 3, and 4.

Referring to the drawings above, the same level of throwing power was confirmed between the comparative examples, there was no significant difference, it was as low as 30 to 45%.

2. Throwing Power Secondary Evaluation

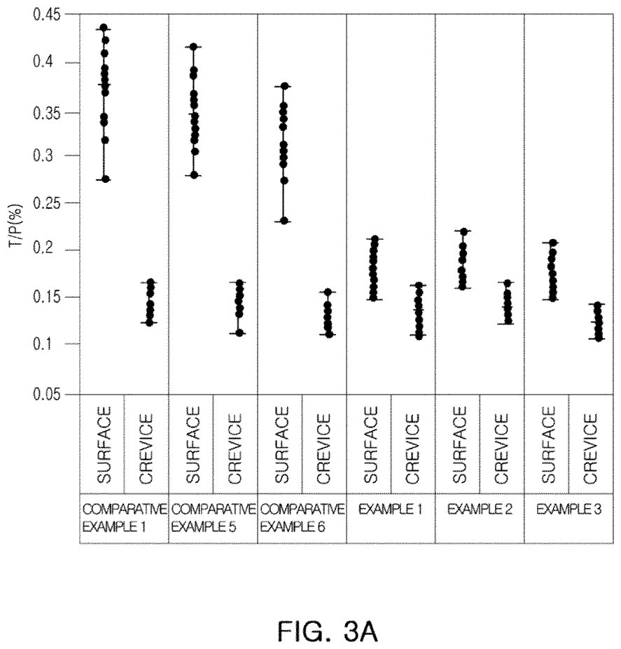

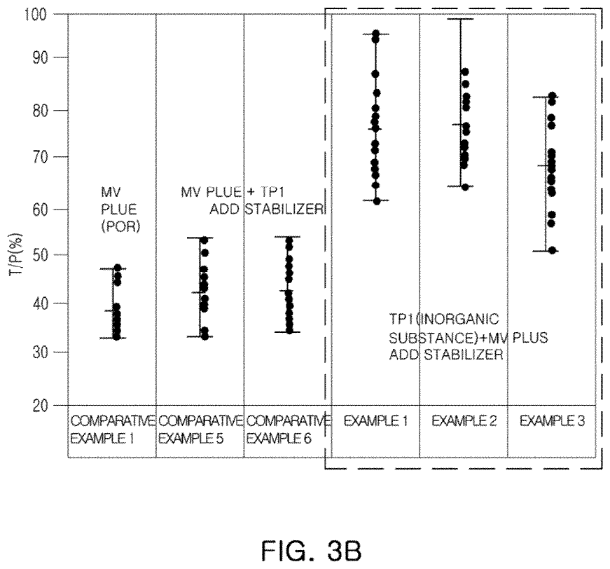

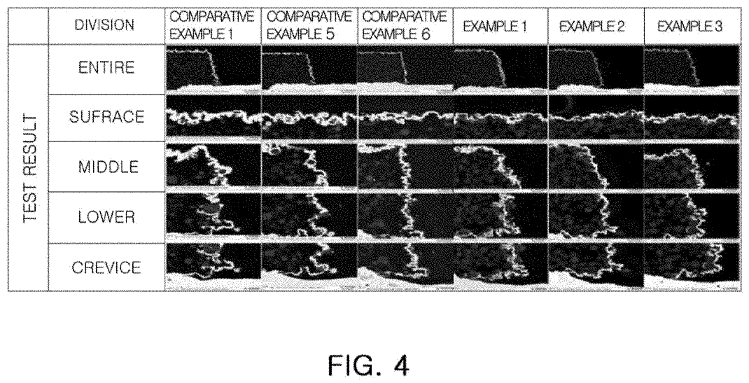

FIGS. 3A and 3B, and FIG. 4 show results of comparing throwing powers (T/P, %) of Comparative Examples 1, 5, and 6 and Examples 1 to 3.

As shown in the drawings, Examples 1 to 3 show that throwing power of the product was significantly improved to 69% or more.

As a result of analyzing a component difference between the copper solution (A) and the basic solution (B) of the copper composition of Examples 1 to 3 and Comparative Examples 1, 5, and 6, it can be confirmed that an effect of improving throwing power was shown by reducing the content of the nickel salt contained in the copper solution (A) and the basic solution (B), respectively (See. Table 8).

TABLE 8

| | Content of nickel salt (%) | | |
|---|---|---|---|
| | Comparative | | |
| | Examples 1, 5, | | |
| Drug name | and 6 | Examples 1 to 3 | Reduction rate |
| Copper solution | 0.5 | 0.1 | ▾80% |
| (A) | | | |
| Basic solution | 1.3 | 0.2 | ▾84.6% |
| (B) | | | |

3. Chemical Copper Thickness Measurement Result

In order to measure the a chemical copper thickness more accurately, chemical copper thickness was measured after copper plating by setting a dipping time to 10′30″ in Comparative Example 7, 9′30″ in Example 4, 8′30″ in Example 5, and 7′30″ in Example 6.

In the case of the chemical copper thickness, compared with Comparative Example 7, the chemical copper thickness was thinned by 0.04 μm in Example 1, thinned by 0.1 μm in Example 4, and thinned by 0.14 μm in Example 5, respectively.

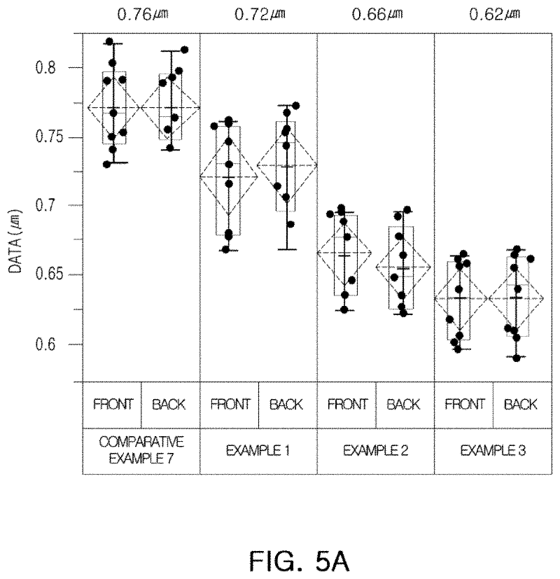

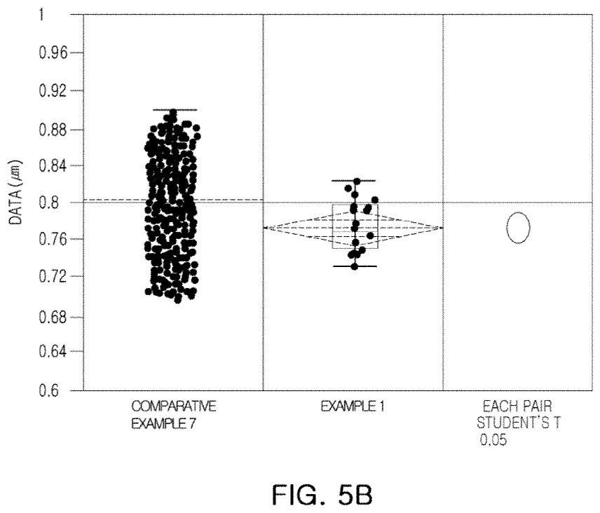

In the case of the thickness by each treatment time, the thickness of chemical copper of Example 1 tended to drop by about 0.05 μm, compared to Comparative Example 7 (see. FIGS. 5A and 5B).

As a result, when the dipping time was reduced to about 1′00″, the plating thickness tended to drop by about 0.05 μm.

4. Throwing Power Measurement Result

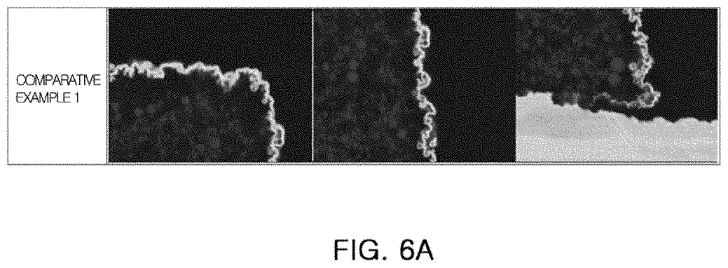

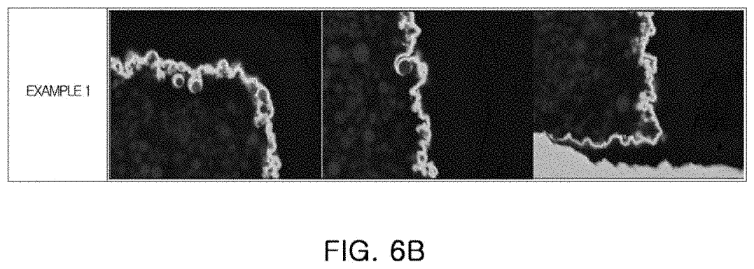

As a result of comparing Comparative Example 1 using a copper solution (A) and a basic solution (B) of the same composition 1 as the conventional MV Plus drug with Example 1 using a copper solution (A) and a basic solution (B) of a composition 2, in Example 1, the chemical copper thickness of a crevice site in the via was measured to be definitely thick (see. FIGS. 6A and 6B).

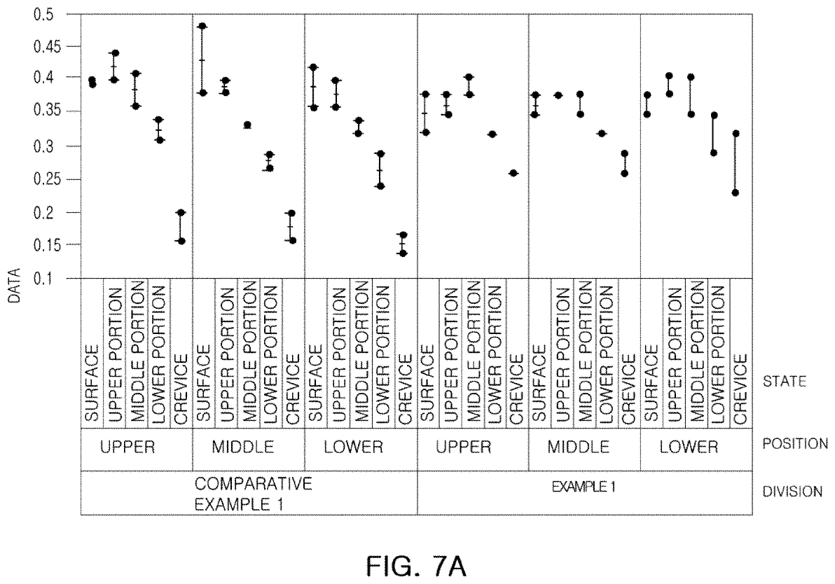

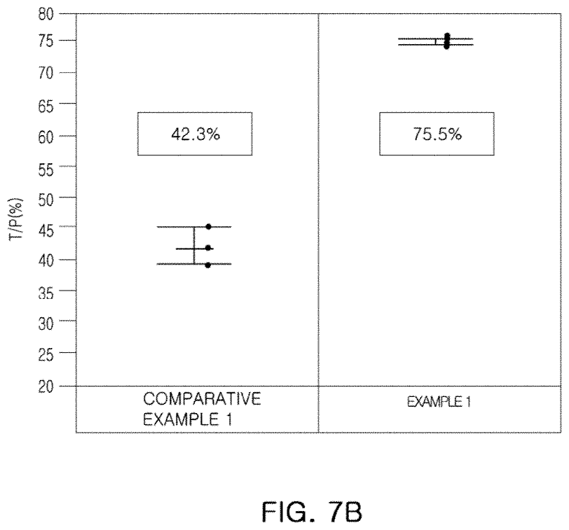

In addition, it can be confirmed that throwing power is improved from 42.3% to 75.5% in Example 1 compared to Comparative Example 1 through a variability chart of FIGS. 7A and 7B and a variability chart of throwing power.

Based on the above results, a surface plating thickness and a gap plating thickness of Comparative Examples 1 to 6 and Examples 1 to 3, and the throwing power measurement results and an improvement effect thereof were shown in Table 9.

TABLE 9

| | | Surface | Crevis | |
|---|---|---|---|---|
| | | plating | plating | |
| | | thickness | thickness | |
| NO | T/P(%) | (μm) | (μm) | Results |
| CE1 | 39 | 0.380 | 0.149 | — |
| CE2 | 40 | 0.410 | 0.164 | No |
| | | | | Significant |
| | | | | difference |
| CE3 | 39 | 0.347 | 0.135 | No |
| | | | | Significant |
| | | | | difference |
| CE4 | 40 | 0.302 | 0.12 | No |
| | | | | Significant |
| | | | | difference |
| CE5 | 43 | 0.350 | 0.149 | No |
| | | | | Significant |
| | | | | difference |
| CE6 | 43 | 0.317 | 0.136 | No |
| | | | | Significant |
| | | | | difference |
| Example 1 | 76 | 0.185 | 0.140 | T/P |
| | | | | improvement |
| Example 2 | 77 | 0.185 | 0.142 | T/P |
| | | | | improvement |
| Example 3 | 0.69 | 0.187 | 0.128 | T/P |
| | | | | improvement |
| Site TEST | 46 | 0.407 | 0.185 | — |
| CE1 | | | | |
| Site TEST | 79 | 0.306 | 0.247 | T/P |
| Example 1 | | | | improvement |

In addition, as a result of comparing throwing power of the product subjected to copper plating with the copper plating composition according to Comparative Example and the product subjected to copper plating with the copper plating composition according to Example 1, it can be observed that Example 1 (79%) had a high throwing power compared to Comparative Example 1 (46%), and copper (Cu) plating was formed at a uniform thickness at all measurement points (see. FIGS. 7A and 7B).

5. Peel Strength Measurement Result

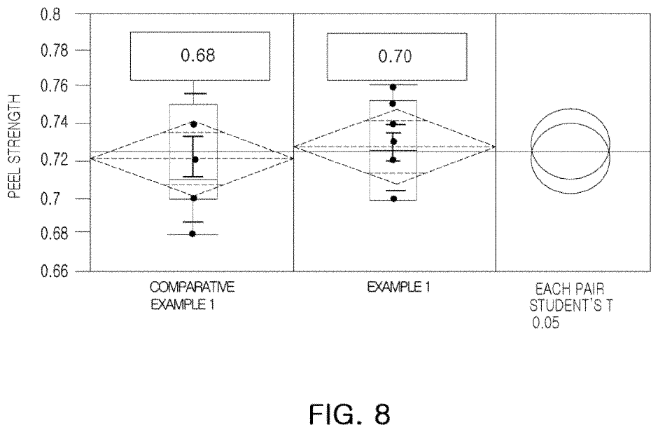

As a result of measuring peel strength of Comparative Example 1 and Example 1, a value of peel strength was measured to be 0.65 and 0.70, and it was confirmed that adhesion was at the same level in both Comparative Example 1 and Example 1 (See. FIG. 8).

6. Coverage Result in Vias

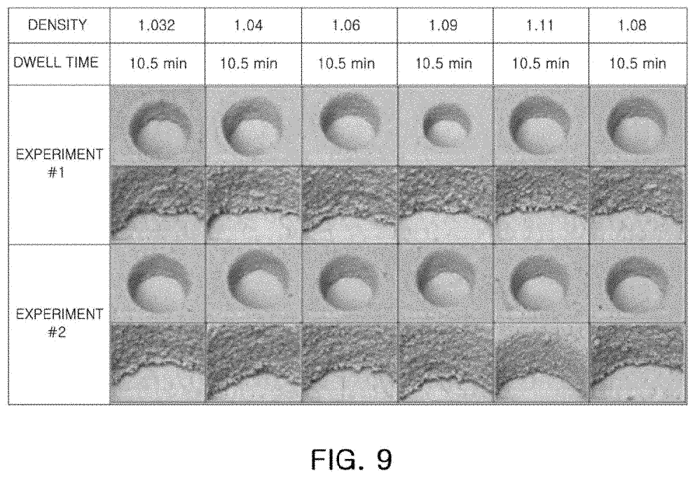

In a product including Example 1, after comparing a coverage in vias, regardless of density of the copper solution and the basic solution of Example 1 (1.032-1.11 g/L) for the chemical copper drug, in the tested density, it was confirmed that the plating was very good without unplating in all cases (see FIG. 9). The coverage result of FIG. 9 was confirmed through repeated experiments (Experiments #1, #2).

While the present invention has been shown and described in connection with the exemplary embodiments, it will be apparent to those skilled in the art that modifications and variations can be made without departing from the spirit and scope of the invention as defined by the appended claims.

What is claimed is:

1. An electroless copper plating composition, comprising:
a copper solution (A) including a copper salt, a nickel salt, and a complexing agent;
a basic solution (B) including a nickel salt, a complexing agent, and a basic compound; and
a stabilizer (C),
wherein a total content of the nickel salt is 0.05 to 1 part by weight, inclusive, relative to a total weight of the copper solution (A) and the basic solution (B).

2. The electroless copper plating composition of claim 1, wherein a content of the nickel salt in the basic solution (B) is 0.05 to 1 part by weight, inclusive, relative to a total weight of the basic solution (B).

3. The electroless copper plating composition of claim 1, wherein a content of the nickel salt in the copper solution (A) is 0.05 or more and less than 0.5 parts by weight, inclusive, relative to a total weight of the copper solution (A).

4. The electroless copper plating composition of claim 1, wherein a content of the copper salt is 10 to 15 parts by weight, inclusive, relative to a total weight of the copper solution (A).

5. The electroless copper plating composition of claim 1, wherein the copper salt comprises copper sulfate (CuSO₄), and the nickel salt comprises nickel sulfate (NiSO₄).

6. The electroless copper plating composition of claim 1, wherein a complexing agent included in the copper solution (A) comprises tartaric acid, and
a content of the tartaric acid is 1 to 5 parts by weight, relative to a total weight of the copper solution (A).

7. The electroless copper plating composition of claim 1, wherein a complexing agent included in the basic solution (B) comprises a Rochelle salt, and
a content of the Rochelle salt is 35 to 45 parts by weight, relative to a total weight of the basic solution (B).

8. The electroless copper plating composition of claim 1, wherein a basic compound included in the basic solution (B) comprises sodium hydroxide (NaOH), and
a content of the basic compound is 5 to 10 parts by weight, relative to a total weight of the basic solution (B).

9. The electroless copper plating composition of claim 1, wherein a content of the stabilizer is 1 to 10 parts by weight, relative to a total weight of the electroless copper plating composition.

10. The electroless copper plating composition of claim 1, wherein the stabilizer comprises NaCN.

11. The electroless copper plating composition of claim 1, further comprising: a starter,
wherein the starter is 1 to 5 parts by weight, relative to a total weight of the electroless plating solution composition.

12. The electroless copper plating composition of claim 1, further comprising: a reducing agent,
wherein the reducing agent is 10 to 20 parts by weight, relative to the total weight of the electroless plating solution.

13. A product copper plated with the electroless copper plating composition of claim 1.

14. The product of claim 13, wherein a thickness of the copper plating is 0.8 μm or less.

15. The product of claim 13, wherein throwing power (T/P) of the product is 65% or more.

16. The product of claim 13, wherein a line/space (L/S) of the product is 5 μm/5 μm or less.

17. The product of claim 13, wherein the product is a printed circuit board, an integrated circuit board, a panel level package (PLP), a redistribution layer (RDL), an interconnect device, a wafer, a display component or a plastic component.

18. A method for preparing an electroless copper plating, comprising: a step of dipping a product in the electroless copper plating composition according to claim 1.

19. The method for preparing an electroless copper plating of claim 18, wherein a dipping time of the step of dipping is 5 to 15 minutes.

20. The method for preparing an electroless copper plating of claim 18, wherein the throwing power (T/P) thereof is 65% or more.
